(19) United States
(12) Patent Application Publication
(10) Pub. No.: US 2018/0152138 A1
(43) Pub. Date: May 31, 2018

(54) CURRENT SOURCE CIRCUIT AND OSCILLATOR

(71) Applicant: SANKEN ELECTRIC CO., LTD., Niiza-Shi (JP)

(72) Inventors: Junichi SUGITA, Niiza-Shi (JP); Masaru NAKAMURA, Niiza-Shi (JP)

(73) Assignee: SANKEN ELECTRIC CO., LTD., Niiza-Shi (JP)

(21) Appl. No.: 15/469,625

(22) Filed: Mar. 27, 2017

(30) Foreign Application Priority Data
Nov. 28, 2016 (JP) 2016-229901

(51) Int. Cl. H03B 5/12

(52) U.S. Cl. CPC H03B 5/1228; H03B 5/124; H03B 5/1234

(57) ABSTRACT

One or more embodiments of current source circuits may include: a first current source that generates a first current dependent on a threshold value of a MOSFET; a second current source that generates a second current dependent on a voltage in a forward direction of a p-n junction; a first resistor that produces a first voltage based on the first current and the second current; a second resistor that produces a second voltage based on the second current; and an output MOSFET that produces an output current based on a sum of the first voltage and the second voltage.

### CROSS REFERENCE TO RELATED APPLICATIONS

This application claims priority based on 35 USC 119 from prior Japanese Patent Application No. 2016-229901 filed on Nov. 28, 2016, entitled “CURRENT SOURCE CIRCUIT AND OSCILLATOR”, the entire contents of which are hereby incorporated herein by reference.

### BACKGROUND

The disclosure relates to a current source circuit and an oscillator, which includes the current source circuit.

Japanese Examined Patent Application Publication No. Hei 7-52821 (hereinafter referred to as Patent Literature 1 as needed) discloses a voltage-controlled oscillator whose oscillation frequency is determined by a capacitance of a capacitor, a constant current value, and a peak value of an oscillation output.

A CMOS reference current source circuit which is independent of the deviation of a threshold voltage is disclosed in the literature “A CMOS Current Reference Independent of Deviation of Threshold Voltage” Mr. Masashi NEGISHI, Kawori TAKAKUBO, and Hajime TAKAKUBO (IEICE Technical Report CAS2006-3 VLD2006-16, SIP2006-26 (2006-6): hereinafter referred to as Non-Patent Literature 1 as needed). This reference current source circuit operates a MOSFET at a zero-temperature-coefficient point to be described later and generates a current stable depending on temperature. Drain current I_{D} flowing at the zero-temperature-coefficient point is not affected by threshold value V_{TH} of the MOSFET. Thus, this reference current source circuit is a current source with corrected temperature characteristic and manufacturing variation in threshold value V_{TH}.

Drain current I_{D} of an nMOSFET in a saturation region is expressed by Equation (1-1):

$${I}_{D} = \frac{1}{2} μ {C}_{ox} \frac{W}{L} {( {V}_{GS} - {V}_{TH} )}^{2} , \qquad ( 1 \text{-} 1 )$$

where μ denotes the electron mobility, V_{TH} the threshold value of the MOSFET, Cox the gate oxide capacitance, W the gate width, and L the gate length. Since mobility μ and threshold value V_{TH} depend on the temperature, drain current I_{D} changes with temperature even when constant gate-to-source voltage V_{GS} is applied. Moreover, threshold value V_{TH} varies depending on the manufacture.

The nMOSFET has an operating point where, at particular gate-to-source voltage V_{GS}, the temperature characteristic of the electron mobility and the temperature characteristic of threshold value V_{TH} cancel out each other and thus the temperature dependence of drain current I_{D} is almost cancelled out. This operating point is referred to as the zero-temperature-coefficient point (ZTCP). Voltage V_{GS} at the zero-temperature-coefficient point is denoted by V_{ZTCP}. A current with corrected temperature dependence can be obtained by operating the nMOSFET at the zero-temperature-coefficient point.

Mobility μ and threshold value V_{TH} are expressed by Equations (1-2) and (1-3) below, respectively:

$$\begin{matrix}μ = {{μ}_{0} ( \frac{T}{{T}_{0}} )}^{- \frac{3}{2}} , & ( 1 \text{-} 2 ) \\ {V}_{TH} = {V}_{TH} ( {T}_{0} ) - {α}_{T} ( T - {T}_{0} ) , & ( 1 \text{-} 3 )\end{matrix}$$

where μ₀ is a proportional constant, T is the absolute temperature, T₀ is the reference absolute temperature, and α_{T} is the temperature coefficient of threshold value V_{TH}. From Equations (1-1), (1-2), and (1-3), V_{ZTCP} becomes as follows:

V_{ZTCP}=V_{TH}+4/3α_{T}T (1-4).

Equation (1-4) can be achieved with the current source circuit illustrated in FIG. 1A. The first term of Equation (1-4) is achieved with INTAT circuit 11 and the second term is achieved with IPTAT circuit 12. In particular, Non-Patent Literature 1 achieves IPTAT circuit 12 using a weak inversion region (region where voltage V_{GS} is operated at a voltage smaller than threshold value V_{TH} of the MOSFET and thus the drain current is small) of the MOSFET.

Voltage V_{ZTCP} deviates because it is affected by threshold value V_{TH}. However, INTAT circuit 11 makes it possible to obtain V_{ZTCP}, which depends on the deviation of threshold value V_{TH}. Thus, the manufacturing variation in threshold value V_{TH} can be corrected. As described above, biasing at the zero-temperature-coefficient point makes it possible to obtain a constant current source with a corrected temperature characteristic and manufacturing variation in threshold value V_{TH}.

### SUMMARY

One or more embodiments of current source circuits may include: a first current source that generates a first current dependent on a threshold value of a MOSFET; a second current source that generates a second current dependent on a voltage in a forward direction of a p-n junction; a first resistor that produces a first voltage based on the first current and the second current; a second resistor that produces a second voltage based on the second current; and an output MOSFET that produces an output current based on a sum of the first voltage and the second voltage.

One or more embodiments of oscillator may include: the current source circuit described above paragraph; a capacitor; and a periodic signal producing section which causes the capacitor to perform at least one of charge and discharge using a current produced based on the output current of the output MOSFET, thereby producing a desired periodic signal.

### BRIEF DESCRIPTION OF DRAWINGS

FIGS. 1A and 1B are each a configuration diagram of a current source circuit according to one or more embodiments.

FIG. 2 is a diagram illustrating a specific circuit configuration of the current source circuit according to one or more embodiments.

FIG. 3 is a diagram illustrating a circuit configuration of an oscillator according to one or more embodiments.

FIG. 4 illustrates timing charts of various sections for explaining an operation of the oscillator illustrated in FIG. 3.

FIG. 5 is a diagram illustrating an example of a related current source.

FIG. 6 is a diagram illustrating a modification of the current source circuit.

### DETAILED DESCRIPTION

Embodiments of the invention are explained with referring to drawings. In the respective drawings referenced herein, the same constituents are designated by the same reference numerals and duplicate explanation concerning the same constituents is basically omitted. All of the drawings are provided to illustrate the respective examples only. No dimensional proportions in the drawings shall impose a restriction on the embodiments. For this reason, specific dimensions and the like should be interpreted with the following descriptions taken into consideration. In addition, the drawings include parts whose dimensional relationship and ratios are different from one drawing to another.

### Embodiment 1

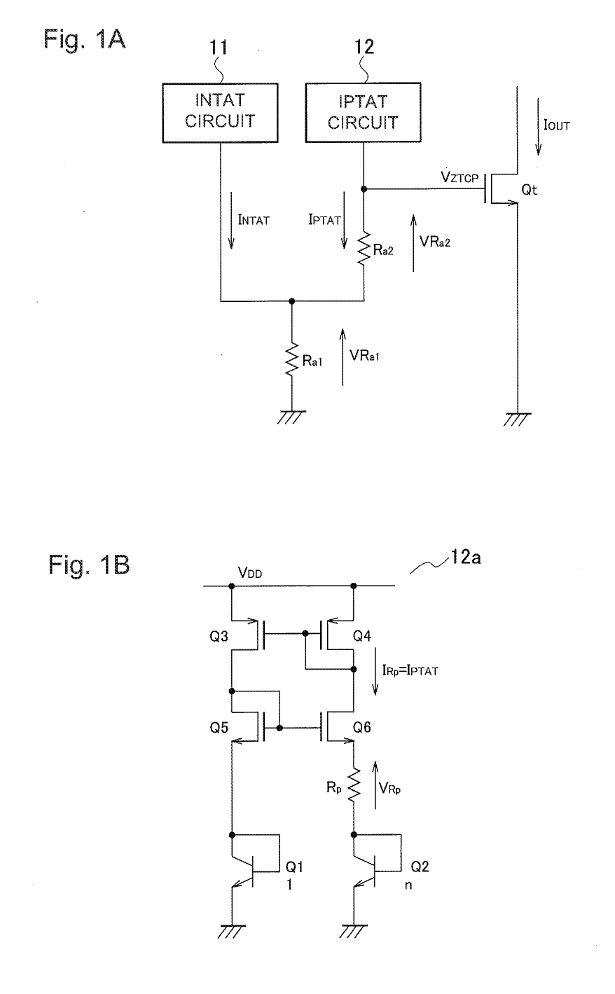

FIGS. 1A and 1B are each a diagram illustrating a circuit configuration of current source circuits of one or more embodiments. Drain current I_{D} of an nMOSFET in a saturation region can be expressed with Equation (1-1). It is possible to obtain current I_{OUT} with a corrected temperature characteristic and manufacturing variation in threshold value V_{TH} by biasing and operating the MOSFET at voltage V_{ZTCP} at a zero-temperature-coefficient point.

As illustrated in FIG. 1A, the current source circuit to generate voltage V_{ZTCP} includes: INTAT (Negatively-Proportional-To-Absolute-Temperature) circuit 11; IPTAT (Proportional-To-Absolute-Temperature) circuit 12; resistor Ra1 which has one end grounded and the other end connected to an output of INTAT circuit 11 and to one end of resistor Ra2; and resistor Ra2 which has one end connected to resistor Ra1 and the other end connected to IPTAT circuit 12 and to a gate of current-generating element Qt.

INTAT circuit 11 constitutes a first current source which generates a first current with a negative temperature dependence and dependent on a threshold value of a MOSFET. IPTAT circuit 12 constitutes a second current source which generates a second current with a positive temperature dependence and dependent on a voltage in a forward direction of a p-n junction.

Current INTAT generated by INTAT circuit 11 and current IPTAT generated by IPTAT circuit 12 flow through resistor Ra1 to produce voltage VRa1, and current IPTAT generated by IPTAT circuit 12 flows through resistor Ra2 to produce voltage VRa2. As voltage V_{ZTCP} at the zero-temperature-coefficient point, the voltage obtained by summing up voltage VRa1 and voltage VRa2 is applied to the gate of current-generating element Qt including the MOSFET.

A description is provided for a configuration of IPTAT circuit 12a illustrated in FIG. 1B, which is included in the current source circuit illustrated in FIG. 1A. IPTAT circuit 12a includes bipolar transistors Q1 and Q2, MOSFETs Q3 to Q6, and resistor Rp.

A source of pMOSFET Q3 and a source of pMOSFET Q4 are connected to power supply V_{DD}, and a gate of pMOSFET Q3 and a gate of pMOSFET Q4 are connected to a drain of nMOSFET Q6. A drain and a gate of nMOSFET Q5 and a gate of MOSFET Q6 are connected to one another. The drain and the gate of MOSFET Q5 are connected to a drain of MOSFET Q3. MOSFET Q3 and MOSFET Q4 constitute a current mirror circuit, and MOSFET Q5 and MOSFET Q6 constitute a current mirror circuit.

A source of MOSFET Q5 is connected to a collector and a base of bipolar transistor Q1. A source of MOSFET Q6 is connected to a collector and a base of bipolar transistor Q2 via resistor Rp. An emitter of each of bipolar transistors Q1 and Q2 is grounded. Bipolar transistors Q1 and Q2 have an emitter area ratio of 1:n (positive integer).

Voltage VRp to be applied to resistor Rp is expressed with Equation (2-1):

$${V}_{Rp} = \frac{kT}{q} ln ( n ) , \qquad ( 2 \text{-} 1 )$$

where k denotes the Boltzmann constant, q the electric charge, and n the ratio of the emitter area of bipolar transistor Q2 to that of Q1.

Current IRp to flow through resistor Rp is expressed in the form of Equation (2-2):

$${I}_{Rp} = \frac{kT}{{R}_{p} q} ln ( n ) ( = {I}_{PTAT} ) . \qquad ( 2 \text{-} 2 )$$

The temperature characteristic of current IRp is expressed in the form of Equation (2-3):

$$\frac{\partial {I}_{Rp}}{\partial T} = \frac{k}{{R}_{p} q} ln ( n ) . \qquad ( 2 \text{-} 3 )$$

As can be seen in Equation (2-3), the temperature characteristic of current IRp is positive. Current IRp is current IPTAT which increases in proportion to the temperature. It is possible to represent the second term of Equation (1-4) after current IRp is replicated using the current mirror circuit or the like and converted to a voltage with a resistor of the same type as that of resistor Rp. Since a relative error between resistors is small especially in an integrated circuit, it is possible to represent the second term of Equation (1-4) with good accuracy.

As described above, in the current source circuit illustrated in FIGS. 1A and 1B, each of bipolar transistors Q1 and Q2 has a collector and a base connected to each other, forming a p-n junction by the base and the emitter. As a result, the p-n junction functions as a diode. The diode allows little current to flow through below forward-direction voltage Vf, while at forward-direction voltage Vf or above, the diode allows an increasingly large current to flow through. The current through the base of each of bipolar transistors Q1 and Q2 is large because a voltage equal to or greater than forward-direction voltage Vf is applied thereto.

Thus, it is possible to fabricate IPTAT generating circuit 12a using bipolar transistors or diodes and to guarantee a current level without use of the weak inversion region. Hence, IPTAT circuit 12a of the current source circuit can be fabricated which is less likely to be affected by leakage currents at high temperature, switching noise, and the like.

In the current source circuit illustrated in FIG. 1, the collector and the base of each of bipolar transistors Q1 and Q2 are connected to each other to form a p-n junction of the base and the emitter, and this p-n junction is allowed to function as a diode. Alternatively, for example, the emitter and the base of each of bipolar transistors Q1 and Q2 may be connected to each other to form a p-n junction of the base and the collector, and this p-n junction may be allowed to function as a diode. As another option, a p-n junction of a body diode of a MOSFET may be used.

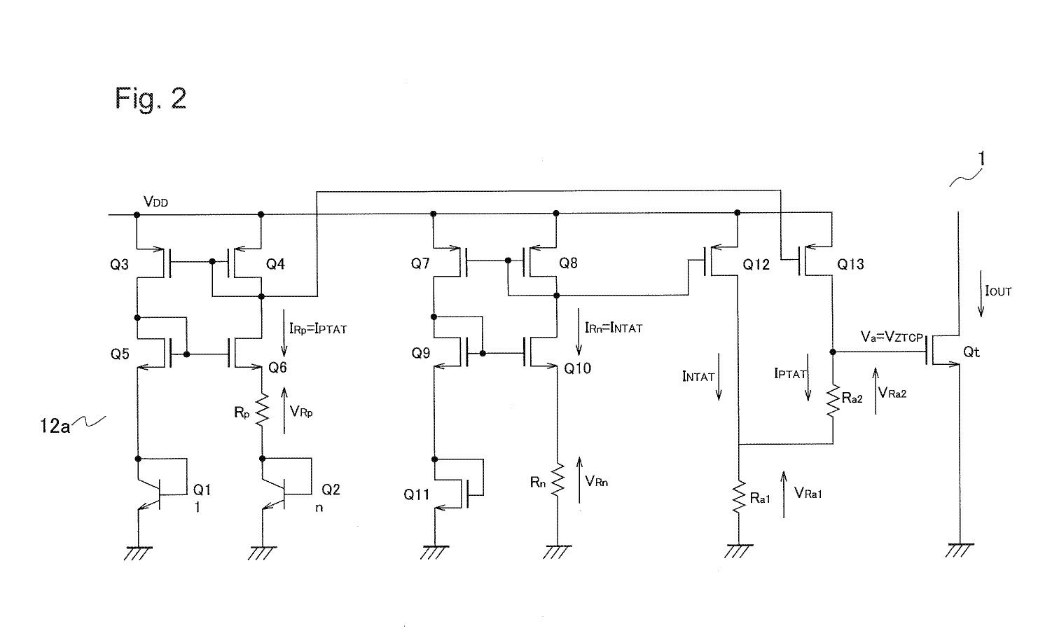

FIG. 2 is a specific circuit configuration diagram of the current source circuit. The current source circuit illustrated in FIG. 2 includes, in addition to IPTAT circuit 12a illustrated in FIG. 1B, an INTAT circuit including MOSFETs Q7 to Q11 and resistor Rn, a current mirror circuit including MOSFETs Q4 and Q13 as well as MOSFETs Q8 and Q12, and current-outputting element Qt.

A source of pMOSFET Q7 and a source of pMOSFET Q8 are connected to power supply V_{DD}. A drain of MOSFET Q8 is connected to a gate thereof. A gate of pMOSFET Q7 and the gate and the drain of pMOSFET Q8 are connected to a drain of nMOSFET Q10 and to a gate of pMOSFET Q12. A drain and a gate of nMOSFET Q9 and a gate of MOSFET Q10 are connected to one another. The drain of MOSFET Q9 and a drain of MOSFET Q7 are connected to each other. MOSFET Q7 and MOSFET Q8 constitute a current mirror circuit. MOSFET Q9, MOSFET Q10, and MOSFET Q11 have such a size ratio that a voltage depending on threshold value V_{TH} of the MOSFETs is produced in resistor Rn.

A source of MOSFET Q9 is connected to a drain and a gate of MOSFET Q11. A source of MOSFET Q11 is grounded. A source of MOSFET Q10 is grounded via resistor Rn.

A source of MOSFET Q12 is connected to power supply V_{DD}, and a drain thereof is connected to one end of resistor Ra1 and to one end of resistor Ra2. A source of pMOSFET Q13 is connected to power supply V_{DD}, a gate thereof is connected to a drain of MOSFET Q4, and a drain thereof is connected to the other end of resistor Ra2 and to a gate of current-generating element Qt.

With the above configuration, I_{PTAT} is allowed to flow through MOSFETs Q4 and Q6, which causes I_{PTAT} to flow through MOSFET Q13 and resistor Ra2. As a result, voltage VRa2 is produced in resistor Ra2. Moreover, I_{NTAT} is allowed to flow through MOSFETs Q8 and Q10, which causes INTAT to flow through MOSFET Q12 and causes I_{NTAT} and I_{PTAT} to flow through resistor Ra1. As a result, voltage VRa1 is produced in resistor Ra1. Let voltage Va=V_{ZTCP} denote the sum of voltage VRa1 and voltage VRa2. This voltage is applied to the gate of current-generating element Qt. Voltage Va is expressed as follows:

$$\begin{matrix}{V}_{a} = {R}_{a 1} {I}_{NTAT} + ( {R}_{a 1} + {R}_{a 2} ) {I}_{PTAT} \\ = \frac{{R}_{a 1}}{{R}_{n}} {V}_{TH} + \frac{{R}_{a 1} + {R}_{a 2}}{{R}_{p}} \cdot \frac{kT}{q} ln ( n ) .\end{matrix} \qquad ( 2 \text{-} 4 )$$

Equation Vₐ=V_{ZTCP} is satisfied by adjusting resistance ratios Rₐ₁/Rₙ and (Rₐ₁+Rₐ₂)/Rₚ such that the first and the second terms of Equation (2-4) become equal to the first and the second terms of Equation (1-4), respectively, making it possible to bias MOSFET Qt at the zero-temperature-coefficient point. Thus, drain current I_{OUT} of MOSFET Qt, which is an output current of the current source of the embodiment, becomes a current with a corrected temperature characteristic and deviation.

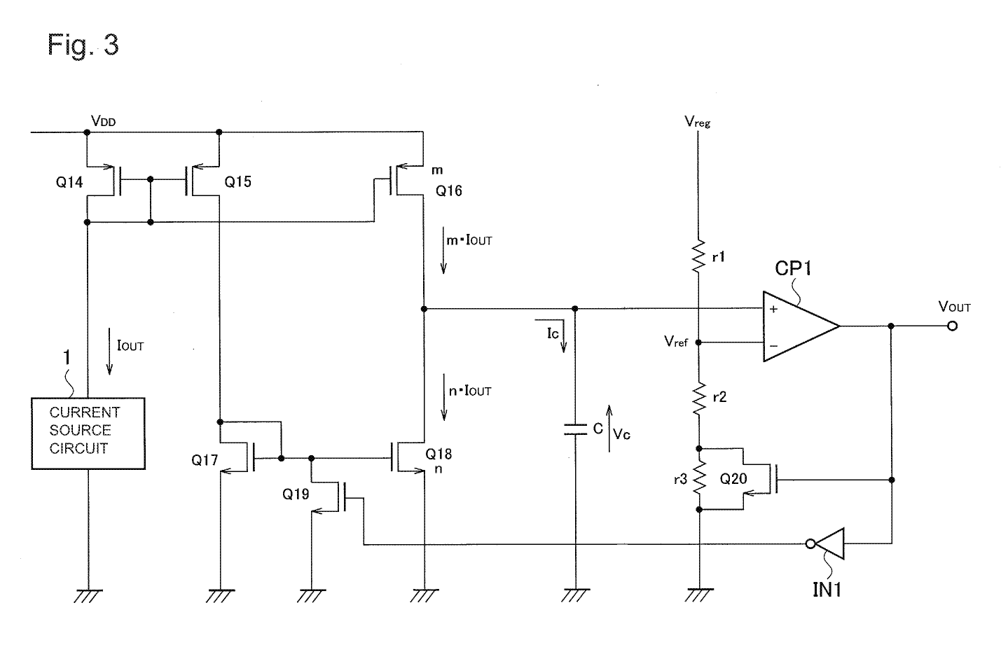

Next, with reference to FIG. 3, a description is provided for an oscillator which includes current source circuit 1 illustrated in FIG. 2. In FIG. 3, one end of current source circuit 1 is grounded, while the other end thereof is connected to a drain of MOSFET Q14. Output current I_{OUT} of current source circuit 1 is supplied to the drain of MOSFET Q14. A source of pMOSFET Q14, a source of pMOSFET Q15, and a source of pMOSFET Q16 are connected to power supply V_{DD}. A gate and the drain of pMOSFET Q14 are connected to each other. In addition, the gate of MOSFET Q14, a gate of pMOSFET Q15, and a gate of pMOSFET Q16 are connected to one end of current source circuit 1. The other end of current source circuit 1 is grounded. MOSFETs Q14, Q15, and Q16 constitute a current mirror circuit.

A drain and a gate of nMOSFET Q17, a gate of nMOSFET Q18, and a drain of nMOSFET Q19 are connected to a drain of MOSFET Q15. A drain of MOSFET Q18, one end of capacitor C, and a non-inverting terminal of comparator CP1 are connected to a drain of MOSFET Q16. A source of MOSFET Q17, a source of MOSFET Q18, and a source of MOSFET Q19 are grounded. The other end of capacitor C is grounded. MOSFETs Q17 and Q18 constitute a current mirror circuit.

The letter m beside pMOSFET Q16 denotes a ratio of the corresponding current mirror circuit, and pMOSFET Q16 multiplies output current I_{OUT} of current source circuit 1 by m. The letter n beside nMOSFET Q18 denotes a ratio of the corresponding current mirror, and nMOSFET Q18 multiplies output current I_{OUT} of current source circuit 1 by n.

A series circuit including resistor r1, resistor r2, and resistor r3 is connected between power supply Vreg and the ground. When the voltage on capacitor C is equal to or greater than the voltage on the connection point between resistor r1 and resistor r2, comparator CP1 outputs H voltage to a gate of nMOSFET Q20 and to inverter IN1.

Current mirror circuits Q14 to Q16, current mirror circuits Q17 and Q18, MOSFET Q19, comparator CP1, MOSFET Q20, inverter IN1, resistors r1 to r3, and capacitor C constitute a periodic signal producing section of embodiment. The periodic signal producing section causes capacitor C described above to perform at least one of charge and discharge using a current produced based on output current I_{OUT} of current-generating element Qt, and thereby causes capacitor C to produce a desired periodic signal.

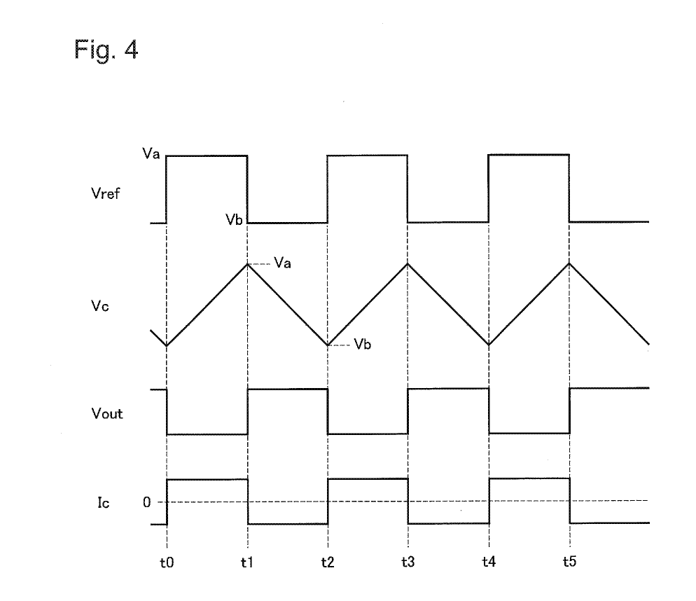

Next, with reference to timing charts of various sections illustrated in FIG. 4, a description is provided for an operation of the oscillator illustrated in FIG. 3. In FIG. 4, Vref denotes a reference voltage applied to an inverting input terminal of comparator CP1, Vc a voltage between both ends of capacitor C, and V_{OUT} an output voltage of comparator CP1.

First, during the interval from time t0 to t1, MOSFET Q20 is turned off and resistor r3 does not experience a short circuit. In addition, reference voltage Vref is Va (Va>Vb), which is generated due to the divided voltages on resistors r1, r2, and r3. Moreover, voltage Vc between both ends of the capacitor satisfies Vc<Va. Thus, output V_{OUT} of comparator CP1 is set to L voltage, and MOSFET Q19 is turned on via inverter IN1 and the gate of MOSFET Q18 is grounded. This causes current mI_{OUT}, which is output current I_{OUT} of current source circuit 1 multiplied by m, to flow from MOSFET Q16 into capacitor C. As a result, capacitor C is charged with current mI_{OUT}. For this reason, voltage Vc on capacitor C continues to increase linearly.

Next, during the interval from time t1 to t2, MOSFET Q20 is turned on and resistor r3 experiences a short circuit. In addition, reference voltage Vref is Vb, which is generated due to the divided voltages on resistors r1 and r2. Moreover, voltage Vc between both ends of the capacitor satisfies Vc>Vb. Thus, output V_{OUT} of comparator CP1 is set to H voltage, and MOSFET Q19 is turned off via inverter IN1 and the gate of MOSFET Q18 is disconnected from the ground. This causes Q17 and Q18 to operate as a current mirror and capacitor C to discharge with current nI_{OUT}−mI_{OUT}, allowing a current to flow to the ground side via MOSFET Q18. For this reason, voltage Vc of capacitor C continues to decrease.

During the next interval from time t2 to t3, the operation is the same as that during the interval from t0 to t1. To be more specific, the interval from time t0 to t2 is period T of an oscillation signal of this oscillator.

Besides, in FIG. 3, output current I_{OUT} is a current with a corrected temperature characteristic and manufacturing variation in threshold value V_{TH}. As can be seen in Equation (1-1), output current I_{OUT} contains mobility p and gate oxide capacitance Cox of current-generating element Qt. Biasing at voltage V_{ZTCP} of zero-temperature-coefficient point makes it possible to correct the effects of the temperature characteristic and the manufacturing variation of threshold value V_{TH}, as well as the effect of the temperature characteristic of mobility μ. However, there remains the effect of the manufacturing variation in mobility p as well as the effects of the temperature characteristic and the manufacturing variation of gate oxide capacitance Cox. Here, let output current I_{OUT} be expressed as follows:

I_{OUT}=Cₒₓ·α (2-5),

where Cox denotes the gate oxide capacitance, and the term a collectively denotes the factors of output current I_{OUT} other than Cox and is affected by mobility μ.

In FIG. 3, let Va denote reference voltage Vref when output voltage V_{OUT} is at L voltage, and let Vb denote reference voltage Vref when output voltage V_{OUT} is at H voltage. Then, period T of the oscillator is expressed by Equation (2-6):

$$T = \frac{C}{{I}_{OUT}} \cdot ( \frac{1}{m} + \frac{1}{n - m} ) \cdot ( {V}_{a} - {V}_{b} ) . \qquad ( 2 \text{-} 6 )$$

Substitution of Equation (2-5) into Equation (2-6) yields Equation (2-7) as follows:

$$T = \frac{C}{{C}_{ox} \cdot α} \cdot ( \frac{1}{m} + \frac{1}{n - m} ) \cdot ( {V}_{a} - {V}_{b} ) . \qquad ( 2 \text{-} 7 )$$

The first term of Equation (2-7) has the form C/Cₒₓ. Basically, the structures of C and Cox are substantially the same especially in an integrated circuit because capacitor C are fabricated using a gate oxide film. For the above reason, capacitor C and gate oxide capacitance Cox deviate in a similar manner due to a thickness of the gate oxide film. Additionally, capacitor C and gate oxide capacitance Cox have similar temperature characteristics per unit capacitance. From what have been described above, the manufacturing variations and the temperature characteristics of capacitor C and gate oxide capacitance Cox are cancelled out. Note that although a deviates due to mobility μ, the deviation of mobility μ is small in general.

The above discussion on the oscillator illustrated in FIG. 3 shows that, by appropriately adjusting resistors Ra1 and Ra2 of current source circuit 1 illustrated in FIG. 2, it is possible to fabricate a highly accurate oscillator which has a very low temperature dependence, and is not affected by the manufacturing variations in threshold value V_{TH} and capacitance. Moreover, combination of current source circuit 1 and capacitor C enables construction of an accurate oscillator in which the manufacturing variation and the temperature characteristic of capacitor C are cancelled out.

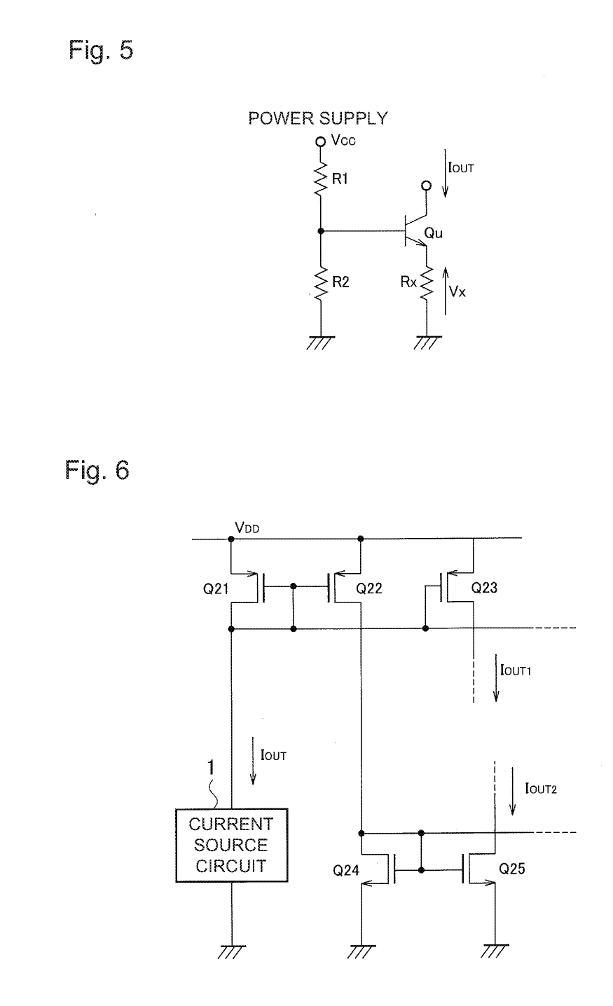

Next, the oscillator illustrated in FIG. 3 and an oscillator of a comparative example are compared to each other. Consider the case where, as the oscillator of the comparative example, a current source circuit illustrated in FIG. 5 is applied to current source circuit 1 of the oscillator illustrated in FIG. 3. Output current I_{OUT} of the current source circuit in FIG. 5 is expressed in the form of Equation (2-8):

$${I}_{OUT} = \frac{{V}_{x}}{{R}_{x}} . \qquad ( 2 \text{-} 8 )$$

Substitution of Equation (2-8) into Equation (2-6) yields Equation (2-9) as follows:

$$T = \frac{{R}_{x} C}{{V}_{x}} ( \frac{1}{m} + \frac{1}{n - m} ) ( {V}_{a} - {V}_{b} ) . \qquad ( 2 \text{-} 9 )$$

The first term of Equation (2-9) has the form of the product of resistor Rx and capacitance C. Since resistor Rx and capacitance C deviate independently of each other, the term Rx·C exhibits a large deviation. Hence, the accuracy of a conventional oscillator is not very good.

### Embodiment 2

FIG. 6 is a diagram illustrating a modification of the current source circuit. The current source circuit illustrated in FIG. 6 includes: a current mirror circuit including pMOSFETs Q21, Q22, and Q23 connected to current source circuit 1; and a current mirror circuit including nMOSFETs Q24 and Q25.

When output current I_{OUT} of current source circuit 1 flows through MOSFET Q21, current I_{OUT1} flows through MOSFET Q23 and current I_{OUT2} flows through MOSFET Q25. To be more specific, output current I_{OUT} can be distributed.

Besides, the current source circuit of the embodiment may be used as a current source circuit for the oscillator to distribute electric currents to other circuits. Moreover, although nMOSFETs are biased with voltage V_{ZTCP} at zero-temperature-coefficient point in Embodiments 1 and 2, pMOSFETs may be biased with voltage V_{ZTCP} at zero-temperature-coefficient point, for example. What is more, although nMOSFET Qt is used in Embodiments 1 and 2, pMOSFET Qt may be used instead.

Additionally, INTAT circuit 11 and IPTAT circuit 12 may have a complementary configuration (pMOSFET and nMOSFET, respectively). Furthermore, when the current mirror circuit is a cascode current mirror circuit, the power supply rejection ratio (PSRR) can be improved. Still further, a start-up circuit may be added to each of INTAT circuit 11 and IPTAT circuit 12 to ensure activation when the power is turned on.

It is to be noted that the invention is not limited to the above-described oscillator illustrated in FIG. 3. This oscillator charges and discharges capacitor C, but may be configured to use a current based on output current I_{OUT} of current source circuit 1 only at the time of charging capacitor C, and to use a switch provided in place of MOSFET Q18 to discharge capacitor C, for example. Alternatively, the oscillator may be configured to use a current based on output current I_{OUT} of current source circuit 1 only at the time of discharging capacitor C, and to use a switch provided in place of MOSFET Q16 to charge capacitor C, for example.

The voltage-controlled oscillator of Patent Literature 1 exhibits a large frequency deviation if the resistance values and the capacitances have a deviation attributed to manufacturing variation. Trimming is required for the purpose of improving the frequency accuracy, and this leads to an increase in chip area. Moreover, since the temperature characteristic of a constant current also depends on manufacturing variation, the temperature dependence of frequency increases as well dependently on manufacturing variation.

In Non-Patent Literature 1, a MOSFET is operated in a weak inversion region. However, use of a weak inversion region causes the following problems. First, a current flowing through the MOSFET operating in the weak inversion region is on the order of several nanoamperes. To be more precise, the current is easily affected by a leakage current from an element because of a low current level. Since leakage current increases especially at high temperatures, it becomes difficult to guarantee high-temperature operation.

In addition, when a switching element operates near the MOSFET, for example, the MOSFET is easily affected by switching noise because of the low current level.

According to the embodiments, the first current source generates the first current dependent on the threshold value of the MOSFET, the second current source generates the second current dependent on the voltage in the forward direction of the p-n junction, the first voltage is produced using the first current and the second current, the second voltage is produced using the second current, and the output current is produced based on the sum of the first voltage and the second voltage. Thus, it is possible to provide a current source circuit and an oscillator which can guarantee a current level without use of the weak inversion region, and are less likely to be affected by leakage currents at high temperature, switching noise, and the like.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

1. A current source circuit comprising:
a first current source that generates a first current dependent on a threshold value of a MOSFET;
a second current source that generates a second current dependent on a voltage in a forward direction of a p-n junction;
a first resistor that produces a first voltage based on the first current and the second current;
a second resistor that produces a second voltage based on the second current; and
an output MOSFET that produces an output current based on a sum of the first voltage and the second voltage.

2. The current source circuit of claim 1, wherein
each of the MOSFET and the output MOSFET is an nMOSFET.

3. The current source circuit of claim 1, wherein
each of the MOSFET and the output MOSFET is a pMOSFET.

4. The current source circuit of claim 1, wherein
the second current source includes a second MOSFET, and
a body diode included in the second MOSFET forms the p-n junction.

5. The current source circuit of claim 1, wherein
the second current source includes a bipolar transistor,
a collector and a base of the bipolar transistor are connected to each other, and the base and an emitter thereof form the p-n junction.

6. The current source circuit of claim 1, wherein
the second current source includes a bipolar transistor,
a base and an emitter of the bipolar transistor are connected to each other, and the base and a collector thereof form the p-n junction.

7. An oscillator comprising:
the current source circuit according to claim 1;
a capacitor; and
a periodic signal producing section which causes the capacitor to perform at least one of charge and discharge using a current produced based on the output current of the output MOSFET, thereby producing a desired periodic signal.

8. The oscillator of claim 7, wherein
the periodic signal producing section outputs the periodic signal with a period based on a ratio of a capacitance of the capacitor to a capacitance based on a gate oxide film of the output MOSFET.
